(19) United States
(12) Patent Application Publication
(10) Pub. No.: US 2017/0357125 A1
(43) Pub. Date: Dec. 14, 2017

(54) DISPLAY DEVICE

(71) Applicant: Japan Display Inc., Minato-ku (JP)

(72) Inventor: Toshio TOJO, Minato-ku (JP)

(73) Assignee: Japan Display Inc., Minato-ku (JP)

(21) Appl. No.: 15/610,671

(22) Filed: Jun. 1, 2017

(30) Foreign Application Priority Data
Jun. 13, 2016 (JP) 2016-117318

(51) Int. Cl. G02F 1/1335; G02F 1/1343; H01L 27/12; G02F 1/136; G02F 1/1362; H01L 51/52

(52) U.S. Cl. CPC G02F 1/133553; G02F 1/136227; H01L 51/5253; H01L 27/12; G02F 1/136; G02F 1/13439; H01L 51/5275

(57) ABSTRACT

To provide a display device including a pixel electrode formed on an insulating surface; an organic layer including a light emitting layer and formed on the pixel electrode; an opposed electrode formed on the organic layer; a first inorganic insulating film formed on the opposed electrode; a first intermediate film formed on the first inorganic insulating film; and a first organic insulating film formed on the first intermediate film. The refractive index of the first intermediate film is less than the refractive index of the first inorganic insulating film and greater than the refractive index of the first organic insulating film.

### CROSS-REFERENCE TO RELATED APPLICATION

The present application claims priority from Japanese application JP2016-117318 filed on Jun. 13, 2016, the content of which is hereby incorporated by reference into this application.

### BACKGROUND OF THE INVENTION

### 1. Field of the Invention

The present invention relates to a display device.

### 2. Description of the Related Art

In a display device such as an organic Electro Luminescence (EL) display, a light-emitting element, such as an organic light emitting diode (OLED), may be controlled by using a switching element, such as a transistor, to display an image.

Japanese Patent Laid-open Publication No. 2006-164543 discloses a sealing film of an organic EL element, the sealing film including a barrier layer made of silicon nitride and a stress relaxation layer made of at least either one of silicon oxynitride and silicon oxide.

Japanese Patent Laid-open Publication No. 2009-037811 discloses a manufacturing method for manufacturing an organic EL device in which an inorganic film of one layer in a sealing layer is formed using an ion beam sputtering method and other inorganic films in the sealing layer are formed using a method other than the ion beam sputtering method.

Japanese Patent No. 4729759 discloses a sealing film for an organic EL device, the sealing layer having a laminated structure containing at least three layers including alternately laminates silicon nitride film and silicon oxynitride film.

An organic EL display device may include a sealing film for protecting an organic layer. A sealing film may have a structure containing an inorganic insulating film with a small water permeability and an organic insulating film covering a foreign matter. In this case, light may reflect at the interface between the inorganic insulating film and the organic insulating film due to a difference in the refractive index between respective materials forming these films. This may deteriorate light extraction efficiency of the organic EL display device.

### SUMMARY OF THE INVENTION

The object of the preset invention is to provide a display device with reduced light reflection in a sealing layer and improved light extraction efficiency.

A display device according to the present invention includes a pixel electrode formed on an insulating surface; an organic layer including a light emitting layer and formed on the pixel electrode; an opposed electrode formed on the organic laver; a first inorganic insulating film formed on the opposed electrode; a first intermediate film formed on the first inorganic insulating film; and first organic insulating film formed on the first intermediate film, wherein the refractive index of the first intermediate film is less than the refractive index of the first inorganic insulating film and greater than the refractive index of the first organic insulating film.

### BRIEF DESCRIPTION OF THE DRAWINGS

FIG. 1 is a perspective view of an organic EL display device according to an embodiment of the present invention;

FIG. 2 is a wiring diagram of an organic EL panel according to an embodiment of the present invention;

FIG. 3 is a circuit diagram of a pixel of an organic EL panel according to an embodiment of the present invention;

FIG. 4 is a cross sectional view of a pixel of an organic EL panel according to an embodiment of the present invention;

FIG. 5 is an enlarged view of a cross section of a pixel of an organic EL panel according to an embodiment of the present invention;

FIG. 6 illustrates first to third examples of a correlation between a light wavelength and a reflectance of a first inorganic insulating film, a first intermediate film, and a first organic insulating film of an organic EL panel according to an embodiment of the present invention;

FIG. 7 illustrates a correlation between a reflectance and a light wavelength in a first comparative example;

FIG. 8 illustrates fourth to sixth examples of a correlation between a light wavelength and a reflectance of a first organic insulating film, a second intermediate film, a second inorganic insulating film, a third intermediate film, and a second organic insulating film of an organic EL panel according to an embodiment of the present invention;

FIG. 9 illustrates seventh to ninth examples of a correlation between a light wavelength and a reflectance of a first organic insulating film, a second intermediate film, a second inorganic insulating film, a third intermediate film, and a second organic insulating film of an organic EL panel according to an embodiment of the present invention; and

FIG. 10 illustrates a correlation between a reflectance and a light wavelength in second to fourth comparative examples.

### DETAILED DESCRIPTION OF THE INVENTION

The following describes an embodiment of the present invention with reference to the drawings. The disclosure is a mere example, and naturally any modification readily conceived by a person skilled in the art without departing from the gist of the present invention will be included in the range of the present invention. The drawings may illustrate the widths, thicknesses, shapes, or the like, of the respective units more schematically for clarity of explanation as compared with actual aspects. These are mere examples, and should not limit interpretation of the present invention in any way. In this specification and respective drawings, an element similar to that which has been described earlier in connection with a drawing mentioned earlier is given the same reference numeral, and a duplicated description is avoided.

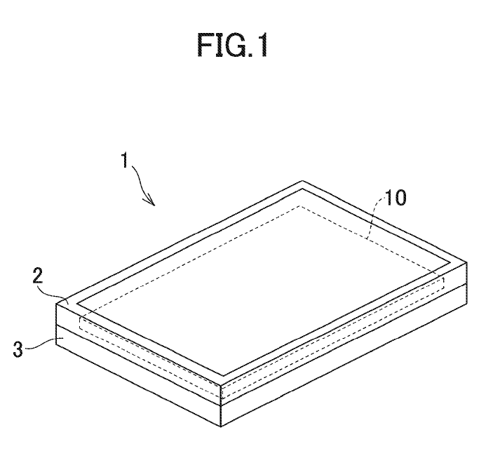

FIG. 1 is a perspective view of an organic EL display device 1 according to an embodiment of the present invention. The organic EL display device 1 includes an organic EL panel 10 fixedly sandwiched by an upper frame 2 and a lower frame 3. The organic EL panel 10 is driven by an external drive circuit, which may be provided inside, that is, between, the upper frame 2 and the lower frame 3, together with the organic EL panel 10, or provided outside via a lead line.

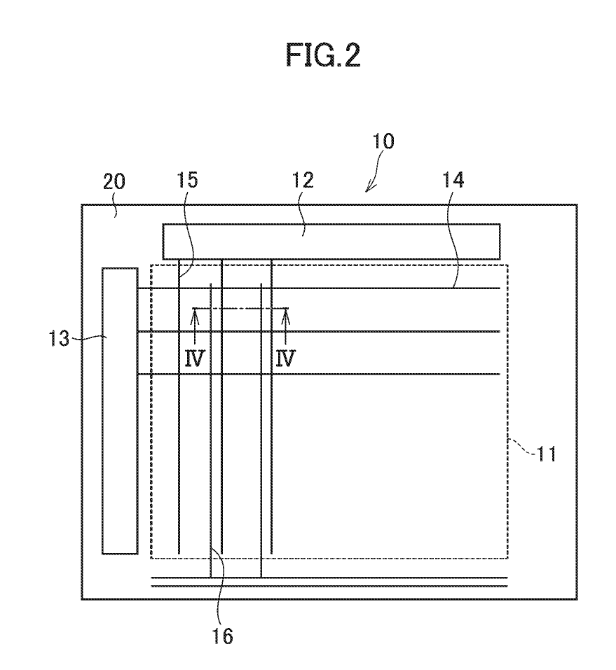

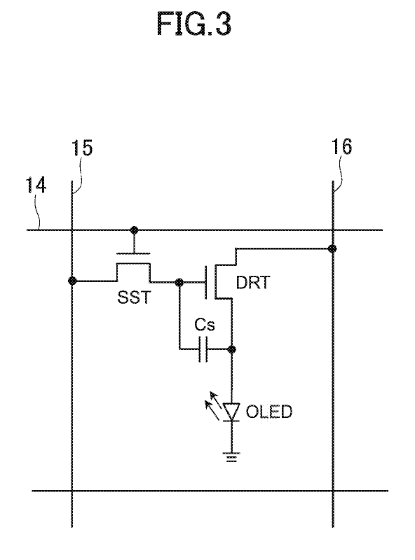

FIG. 2 is a wiring diagram of the organic EL panel 10 according to an embodiment of the present invention. FIG. 3 is a circuit diagram of a pixel of the organic EL panel 10 according to an embodiment of the present invention. The organic EL panel 10 controls respective pixels arranged in a matrix on a display area 11 on a substrate 20, using a video signal drive circuit 12 and a scan signal drive circuit 13, to display an image. The video signal drive circuit 12 is a circuit that generates a video signal to be sent to each pixel, and sends the signal. The scan signal drive circuit 13 generates a scan signal to be sent to a thin film transistor (TFT) formed in each pixel, and sends the signal. The video signal drive circuit 12 and the scan signal drive circuit 13, which are illustrated as formed in two respective positions in FIG. 2, may be formed in a single integrated circuit (IC) or formed separately in three or more positions.

The signal from the scan signal drive circuit 13 is transmitted via a scan signal line 14, which is electrically connected to the gate of a pixel transistor SST formed in each pixel area. The scan signal line 14 is common to the pixel transistors aligned in one row. The pixel transistor SST is a transistor electrically connected via its source or drain to the gate of a drive transistor DRT. The drive transistor DRT is an electric field effect transistor having an n-type channel, for example, with the source thereof electrically connected to the anode of an organic light emitting diode OLED. The cathode of the organic light emitting diode OLED is fixed at the ground potential or negative potential. In the above, a current flows from the anode to cathode in the organic light emitting diode OLED. Meanwhile, the signal from the video signal drive circuit 12 is transmitted via a video signal line 15, which is electrically connected to either the source or drain of the pixel transistor SST. The video signal line 15 is common to the pixel transistors aligned in a single column. With a scan signal applied to the scan signal line 14, the pixel transistor SST is turned on. With a video signal applied to the video signal line 15 while the pixel transistor SST is in an on state, a video signal voltage is applied to the gate of the drive transistor DRT, whereby a voltage in accordance with the video signal is written into the holding capacitor Cs, and the drive transistor DRT is turned on. Here, note that the drain of the drive transistor DRT is electrically connected to a power supply line 16, to which a power supply voltage for causing the organic light emitting diode OLED to emit light is applied. Thus, with the drive transistor DRT turned on, a current in accordance with the video signal voltage flows into the organic light emitting diode OLED, which then emits light.

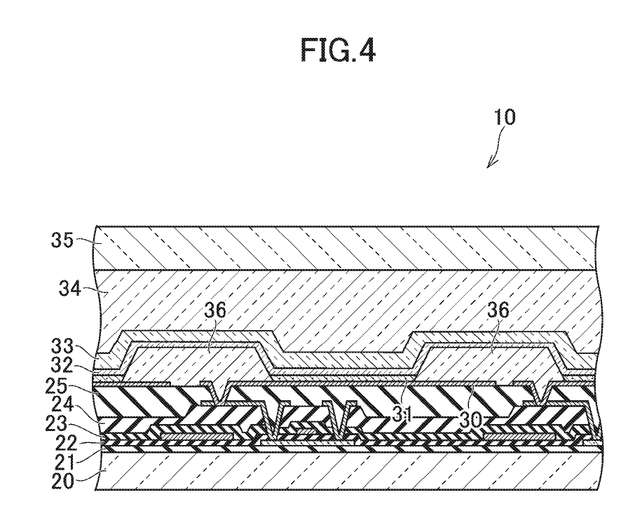

FIG. 4 is a cross sectional view of a pixel of the organic EL panel 10 according to an embodiment of the present invention. This drawing is a cross sectional view of a pixel along the line IV-IV shown in FIG. 2. In the organic EL panel 10 according to this embodiment, a first insulating film 21 is formed on the substrate 20, and a channel of the drive transistor DRT is formed on the first insulating film 21. A second insulating film 22 is formed on the first insulating film 21, and a gate of the drive transistor DRT is formed on the second insulating film 22. A third insulating film 23 is formed on the second insulating film 22, and a fourth insulating film 24 is formed on the third insulating film 23. Each of the second insulating film 22, the third insulating film 23, and the fourth insulating film 24 has a through-hole formed therein. In the through-hole, a source electrode and a drain electrode are formed that are electrically connected to the channel of the drive transistor DRT.

A planarization film 25 is formed on the fourth insulating film 24. In the organic EL panel 10 according to this embodiment, the planarization film 25 is made of organic insulating material and has an insulating surface. A pixel electrode 30 is formed on the upper surface of the planarization film 25. That is, the upper surface of the planarization film 25 is an insulating surface, and the pixel electrode 30 is formed on the insulating surface. A bank 36 is formed on the pixel electrode 30 and the planarization film 25. The bank 36 has an opening formed therein at a position overlapping the pixel electrode 30, and the pixel electrode 30 is partially exposed through the opening. In the opening of the bank 36, an organic layer 31 including a light emitting layer is formed in contact with the exposed part of the pixel electrode 30. That is, the organic layer 31 is formed on the pixel electrode 30, and covers the opening of the bank 36. An opposed electrode 32 is formed on the organic layer 31. The opposed electrode 32 is made of material that allows the light emitted from the organic layer 31 to pass through. The opposed electrode 32 is formed on the organic layer 31 and the bank 36. A sealing film 33 is formed on the opposed electrode 32. A filler 34 is applied onto the sealing film 33. An opposed substrate 35 is fixedly formed on the filler 34.

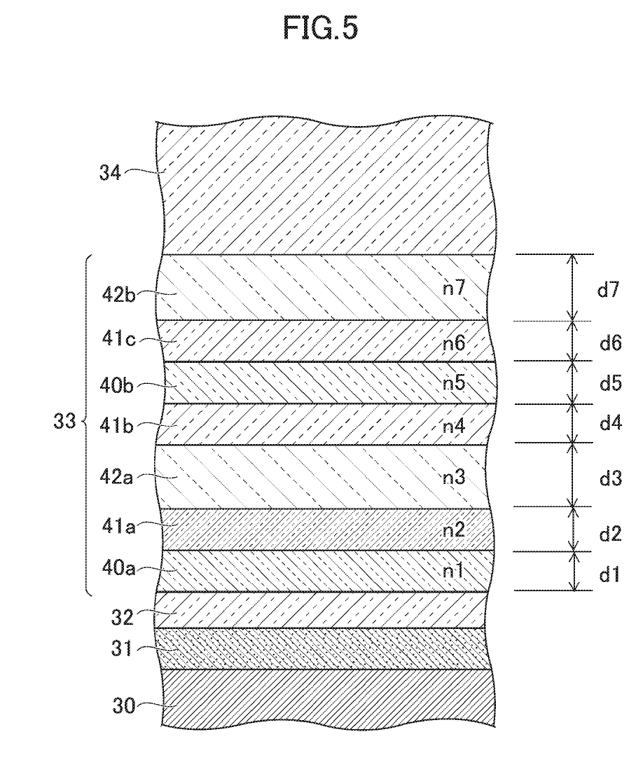

FIG. 5 is an enlarged view of a cross section of a pixel of the organic EL panel according to an embodiment of the present invention. This drawing illustrates a laminated structure of the sealing film 33. In particular, a first inorganic insulating film 40a having a film thickness d1 and a refractive index n1 is formed on the opposed electrode 32. A first intermediate film 41a having a film thickness d2 and a refractive index n2 is formed on the first inorganic insulating film 40a. A first organic insulating film 42a having a film thickness d3 and a refractive index n3 is formed on the first intermediate film 41a. The refractive index n2 of the first intermediate film 41a is less than the refractive index n1 of the first inorganic insulating film 40a and greater than the refractive index n3 of the first organic insulating film 42a. That is, the correlation n1>n2>n3 is held.

In the organic EL panel 10 according to this embodiment, the first inorganic insulating film 40a is made using a silicon nitride film and has the refractive index n1=1.9. The first intermediate film 41a is made using a silicon oxynitride film and has the refractive index n2=1.7. The first organic insulating film 42a is made of resin containing acrylic or epoxy, and has the refractive index n3=1.5. Note that the materials and the respective values of the refractive indexes mentioned above of the first inorganic insulating film 40a, the first intermediate film 41a, and the first organic insulating film 42a are mere examples, and any other materials that hold the correlation n1>n2>n3 can be used.

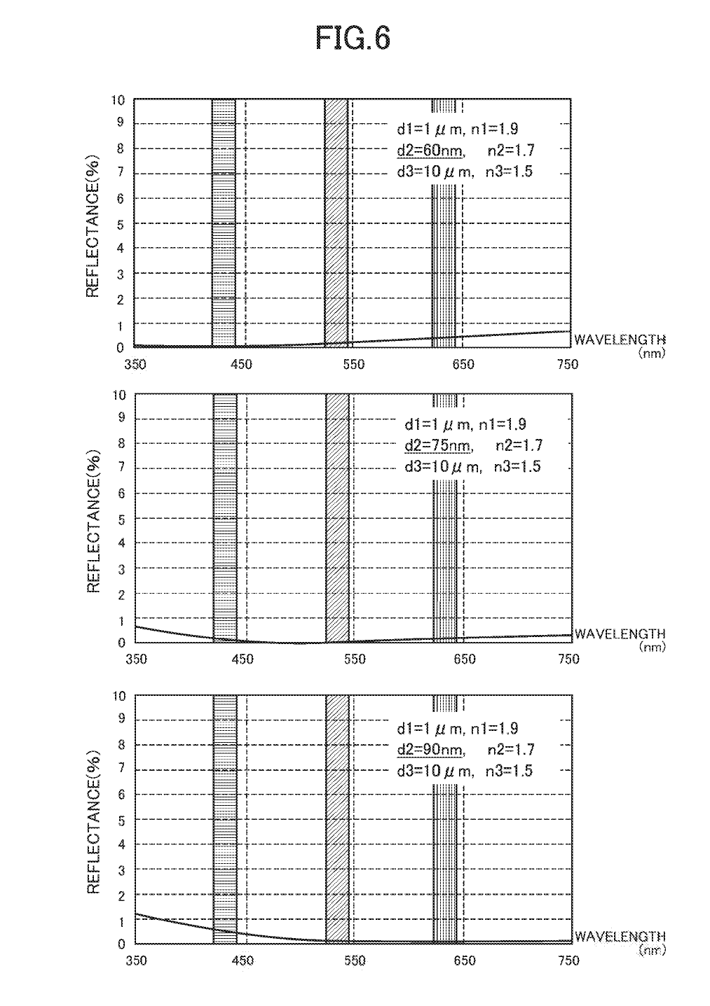

FIG. 6 illustrates first to third examples of the correlation between the light wavelength and the reflectance of the first inorganic insulating film 40a, the first intermediate film 41a, and the first organic insulating film 42a of the organic EL panel 10 according to an embodiment of the present invention. This drawing illustrates a first example in which the film thickness of the first inorganic insulating film 40a is 1 μm, or d1=1 μm, that of the first organic insulating film 42a is 10 μm, or d3=10 μm, and that of the first intermediate film 41a is 60 nm, or d2=60 nm, a second example width d2=75 nm, and the third example with d2=90 nm. Each graph shows a light reflectance (%) with respect to a light wavelength between 350 nm and 750 nm. Note that the light reflectance here refers to the percentage of the light reflected toward the organic layer 31 side by the first inorganic insulating film 40a, the first intermediate film 41a, and the first organic insulating film 42a, in relation to the visible light emitted from the organic layer 31 toward the display surface side of the organic EL panel 10. In each graph, the wavelength range for blue (420 nm to 440 nm in this specification), that for green (525 nm to 545 nm in this specification) and that for red (620 nm to 640 nm) are shown hatched.

In the organic EL panel 10 according to this embodiment, the reflectance of the visible light emitted from the organic layer 31 toward the display surface side and reflected by the first inorganic insulating film 40a, the first intermediate film 41a, and the first organic insulating film 42a changes along a downward convex curve in relation to the wavelength, and takes the minimum value in the visible light wavelength range. In the first example, shown at the top in FIG. 6, the reflectance changes along a downward convex curve in relation to the wavelength, and takes the minimum value (0%) in the blue wavelength range. The reflectance in the first example is equal to or less than 0.5% in the green and red respective wavelength ranges, and takes a very small value over the entire visible light region.

In the second example, shown at the middle in FIG. 6, the reflectance changes along a downward convex curve in relation to the wavelengths, and takes the minimum value (0%) in the green wavelength range. The reflectance in the second example is equal to or less than 0.5% in the blue and red respective wavelength ranges, and takes a vary small value in the entire visible light region. Similarly, in the third example, shown at the bottom in FIG. 6, the reflectance changes along a downward convex curve in relation to the wavelength, and takes the minimum value (0%) in the red wavelength range. The reflectance in the third example is equal to or less than 0.5% in the blue and green respective wavelength ranges, and takes a very small value in the entire visible light region.

According to the organic EL panel 10 according to this embodiment, as the first intermediate film 41a is formed between the first inorganic insulating film 40a and the first organic insulating film 42a to hold the refractive index correlation n1>n2>n3 between the respective materials forming the first inorganic insulating film 40a, the first intermediate film 41a, and the first organic insulating film 42a, a very small reflectance is achieved over the entire visible light region, as shown in FIG. 6, even when the film thickness d2 of the first intermediate film 41a varies by about ±20%. This is because the first intermediate film 41a reduces the gap in the refractive index between the first inorganic insulating film 40a and the first organic insulating film 42a to thereby reduce reflection at the interface. This enables reduction of reflectance in the visible light region independently of the accuracy in a film forming process, and thus can improve the light extraction efficiency. Additionally, in the case where the accuracy in a film forming process is so high that it is possible to control the film thickness d2 of the first intermediate film 41a within the range of about ±5%, it is possible to selectively improve the light extraction efficiency for a partial wavelength band in the visible light region. For example, light extraction efficiency for blue, whose brightness may become lower as compared with those of green and red, can be selectively improved.

According to the organic EL panel 10 according to this embodiment, as the reflectance changes along a downward convex curve in relation to the wavelength and takes the minimum value in the visible light wavelength range, the reflectance will not change significantly even when the film thicknesses and the refractive indexes of the first inorganic insulating film 40a, the first intermediate film 41a, and the first organic insulating film 42a should deviate from the design values by a few percentages, and the reflectance in the visible light region becomes 0.5% or below.

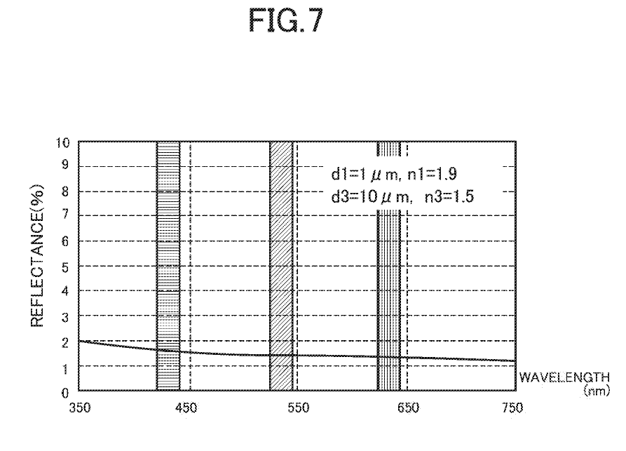

FIG. 7 illustrates a correlation between the reflectance and the light wavelength in a first comparative example. The first comparative example is related to a structure resulting from removing the first intermediate film 41a from the sealing film 33 of the organic EL panel 10 according to this embodiment so that the first inorganic insulating film 40a with the film thickness d1 and the refractive index n1 is formed on the opposed electrode 32, and the first organic insulating film 42a with the film thickness d3 and the refractive index n3 is formed on the first inorganic insulating film 40a. Specifically, the film thickness d1 of the first inorganic insulating film 40a is 1000 nm, or d1=100 nm, and the refractive index n1 of the same is 1.9, or n1=1.9; the film thickness d3 of the first organic insulating film 42a is 10 μm, or d3=10 μm and the refractive index n3 of the same is 1.5, or n3=1.5.

In the first comparative example, the reflectance in the visible light region is 1 to 2%, which is large as compared with that of the organic EL panel 10 according to this embodiment. Although changing along a downward convex curve in relation to the wavelength, the reflectance monotonically decreases with respect to a longer wavelength and does not take the minimum value in the visible light region. Thus, when the film thicknesses and refractive indexes of the first inorganic insulating film 40a and first organic insulating film 42a should deviate from the respective design values by a few percentages, the reflectance may unintendedly become large, which may possibly deteriorate the light extraction efficiency. On the contrary, the organic EL panel 10 according to this embodiment can reduce the reflectance in the visible light region to 0.5% or below, with little possibility that the reflectance unintendedly becomes large. The enables stable increase in the light extraction efficiency.

Returning to FIG. 5, the laminated structure of the sealing film 33 will be further described with reference this drawing. On the first organic insulating film 42a, a second intermediate film 41b having a film thickness d4 and a refractive index n4 is formed. A second inorganic insulating film 40b having a film thickness d5 and a refractive index n5 is formed on the second intermediate film 41b. A third intermediate film 41c having a film thickness d6 and a refractive index n6 is formed on the second inorganic insulating film 40b. A second organic insulating film 42b having a film thickness d7 and a refractive index n7 is formed on the third intermediate film 41c. The refractive index n4 of the second intermediate film 41b is less than the refractive index n5 of the second inorganic insulating film 40b and greater than the refractive index n3 of the first organic insulating film 42a. That is, the correlation n5>n4>n3 is held. The refractive index n6 of the third intermediate film 41c is less than the refractive index n5 of the second inorganic insulating film 40b and greater than the refractive index n7 of the second organic insulating film 42b. That is, the correlation n5>n6>n7 is held.

In the organic EL panel 10 according to this embodiment, the second inorganic insulating film 40b is made using a silicon nitride film and has the refractive index n5=1.9. The second intermediate film 41b and the third intermediate film 41c are each made using a silicon oxynitride film, and have the refractive indexes n4=1.7 and n6=1.7. The second organic insulating film 42b is made of one kind of resin selected from the group consisting of resin including acrylic or epoxy, polyimide, polyethylene naphthalate, and polyethylene terephthalate, and has the refractive index n7=1.5. Note that the respective materials and the respective values of the refractive indexes mentioned above of the second intermediate film 41b, the second inorganic insulating film 40b, the third intermediate film 41c, and the second organic insulating film 42b are mere examples, and any other materials holding the correlation n5>n4>n3 and n5>n6>n7 may be usable.

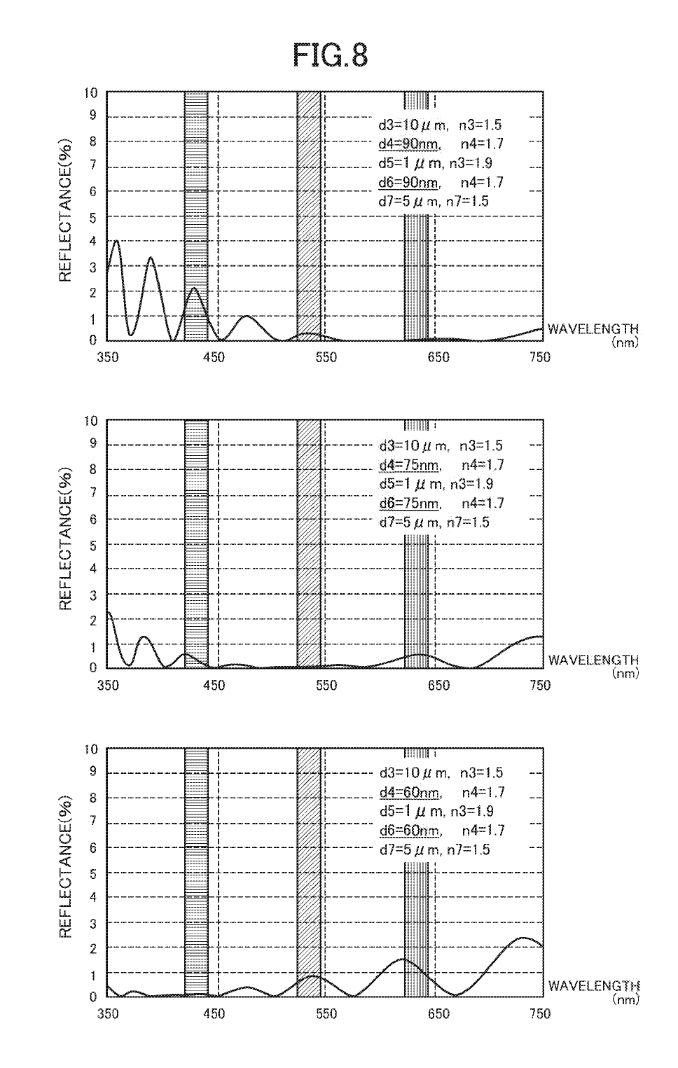

FIG. 8 illustrates fourth to sixth examples of the correlation between the light wavelength and the reflectance of the first organic insulating film 42a, the second intermediate film 41b, the second inorganic insulating film 40b, the third intermediate film 41c, and the second organic insulating film 42b of the organic EL panel 10 according to the embodiment of the present invention. This drawing illustrates the fourth to sixth examples in which the film thickness d4 of the second intermediate film 41b and the film thickness d6 of the third intermediate film 41c are varied. In the fourth to sixth examples, the film thickness d3 of the first organic insulating film 42a, the film thickness d5 of the second inorganic insulating film 40b, and the film thickness d7 of the second organic insulating film 42b are constant. Specifically, the film thickness d3 of the first organic insulating film 42a is 10 μm, or d3=10 μm; the film thickness d5 of the second inorganic insulating film 40b is 1 μm, or d5=1 μm; the film thickness d7 of the second organic insulating film 42b is 5 μm, or d7=5 μm. The fourth example, shown at the top in FIG. 8, is related to a case in which the film thickness d4 of the second intermediate film 41b is 90 nm, or d4=90 nm, and the film thickness d6 of the third intermediate film 41c is 90 nm, or d6=90 nm. The fifth example, shown at the middle in FIG. 8, relates to a case in which the film thickness d4 of the second intermediate film 41b is 75 nm, or d4=75 nm, and the film thickness d6 of the third intermediate film 41c is 75 nm, or d6=75 nm. The sixth example, shown at the bottom in FIG. 8, relates to a case in which the film thickness d4 of the second intermediate film 41b is 60 nm, or d4=60 nm, and the film thickness d6 of the third intermediate film 41c is 60 nm, or d6=60 nm. Each graph shows a light reflectance (%) with respect to a light wavelength between 350 nm and 750 nm. Note that the light reflectance here refers to the percentage of the light reflected toward the organic layer 31 side by the first organic insulating film 42a, the second intermediate film 41b, the second inorganic insulating film 40b, the third intermediate film 41c, and the second organic insulating film 42b in relation to the visible light emitted from the organic layer 31 toward the display surface side of the organic EL panel 10. In each graph, the wavelength range for the blue (420 nm to 440 nm in this specification), that for green (525 nm to 545 nm in this specification) and that for red (620 nm to 640 nm) are shown hatched.

In the organic EL panel 10 according to this embodiment, the reflectance of the visible light emitted from the organic layer 31 toward the display surface side and reflected by the first organic insulating film 42a, the second intermediate film 41b, the second inorganic insulating film 40b, the third intermediate film 41c, and the second organic insulating film 42b vibrates in relation to the wavelength, and the amplitude of vibration takes the minimum value in the visible light wavelength range. In the fourth example, shown at the top in FIG. 8, the reflectance vibrates in relation to the wavelength, and the amplitude of vibration takes the minimum value in the wavelength range for red. The reflectance in the fourth example is equal to or less than 2% in the wavelength range for blue, equal to or less than 0.5% in the wavelength range for green, and about 0% in the wavelength range for red, and takes a small value over the entire visible light region.

In the fifth example, shown at the middle in FIG. 8, the reflectance vibrates in relation to the wavelength, and the amplitude of vibration takes the minimum value in the wavelength range for green. The reflectance in the fifth example is equal to or less than 0.5% in the wavelength range for blue, about 0% in the wavelength range for green, and equal to or less than 0.5% in the wavelength range for red, and takes a small value over the entire visible light region. In the sixth example, shown at the bottom in FIG. 8, the reflectance vibrates in relation to the wavelength, and the amplitude of vibration takes the minimum value in the wavelength range for blue. The reflectance in the sixth example is about 0% in the wavelength range for blue, equal to or less than 1% in the wavelength range for green, and equal to or less than 1.5% in the wavelength range for red, and takes a small value over the entire visible light region.

As illustrated in FIG. 8, according to the organic EL panel 10 according to this embodiment, as the second intermediate film 41b is formed between the first organic insulating film 42a and the second inorganic insulating film 40b, and the third intermediate film 41c is formed between the second inorganic insulating film 40b and the second organic insulating film 42b, to hold the correlation n5>n4>n3, and n5>n6>n7, a small reflectance is achieved over the entire visible light region even when the film thickness d4 of the second intermediate film 41b and the film thickness d6 of the third intermediate film 41c should vary by about ±20%. This is because the second intermediate film 41b reduces the gap in the refractive index between the first organic insulating film 42a and the second inorganic insulating film 40b to thereby reduce reflection at the interface, and the third intermediate film 41c reduces the gap in the refractive index between the second inorganic insulating film 40b and the second organic insulating film 42b to thereby reduce reflection at the interface. This enables reduction of reflectance in the visible light region independently of the accuracy in a film forming process, and thus can improve the light extraction efficiency. Additionally, in the case where the accuracy in film forming process is so high that it is possible to control the film thickness d4 of the second intermediate film 41b and the film thickness d6 of the third intermediate film 41c within the range of about ±5%, it is possible to selectively improve the light extraction efficiency for a partial wavelength band in the visible light region. For example, light extraction efficiency for blue, whose brightness may become lower as compared with those of green and red, can be selectively improved.

According to the organic EL panel 10 according to this embodiment, as the reflectance vibrates in relation to the wavelength and the amplitude of vibration takes the minimum value in the visible light wavelength range, the reflectance will not change significantly even when the film thicknesses and refractive indexes of the first organic insulating film 42a, the second inorganic insulating film 40b, and the second organic insulating film 42b should deviate from the design values by a few percentages, and the reflectance in the visible light region becomes 2% or below.

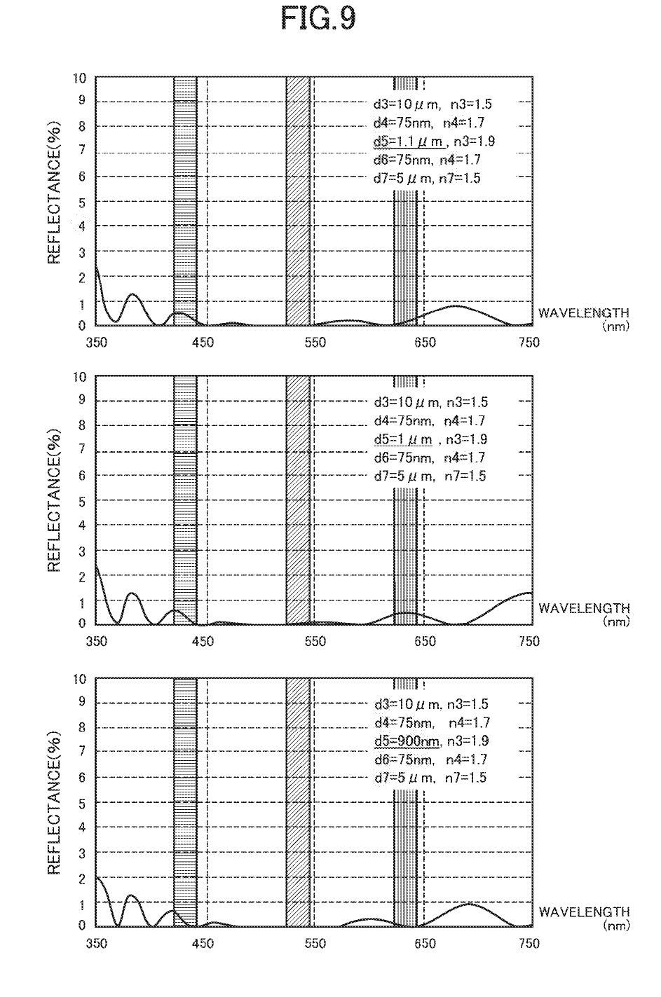

FIG. 9 illustrates seventh to ninth examples of the correlation between the light wavelength and the reflectance of the first organic insulating film 42a, the second intermediate film 41b, the second inorganic insulating film 40b, the third intermediate film 41c, and the second organic insulating film 42b of the organic EL panel 10 according to an embodiment of the present invention. This drawing illustrates the seventh to ninth examples in which the film thickness d5 of the second inorganic insulating film 40b are varied. In the respective examples, the film thickness d3 of the first organic insulating film 42a, the film thickness d4 of the second intermediate film 41b, the film thickness d6 of the third intermediate film 41c, and the film thickness d7 of the second organic insulating film 42b are constant. Specifically, the film thickness d3 of the first organic insulating film 42a is 10 μm, or d3=10 μm, the film thickness d4 of the second intermediate film 41b is 74 nm, or d4=75 nm, the film thickness d6 of the third intermediate film 41c is 75 nm, or d6=75 nm, and the film thickness d7 of the second organic insulating film 42b is 5 μm, or d7=5 μm. The seventh example, shown at the top in FIG. 9, is related to a case in which the film thickness d5 of the second inorganic insulating film 40 is 1.1 μm, or d5=1.1 μm. The eighth example, shown at the middle in FIG. 9, relates to a case in which the film thickness d5 of the second inorganic insulating film 40b is 1 μm, or d5=1 μm. The ninth example, shown at the bottom in FIG. 9, relates to a case in which the film thickness d5 of the second inorganic insulating film 40b is 900 nm, or d5=900 nm. Each graph shows a light reflectance (%) with respect to a light wavelength between 350 nm and 750 nm. Note that the light reflectance here refers to the percentage of the light reflected toward the organic layer 31 side by the first organic insulating film 42a, the second intermediate film 41b, the second inorganic insulating film 40b, the third intermediate film 41c, and the second organic insulating film 42b in relation to the visible light emitted from the organic layer 31 toward the display surface side of the organic EL panel 10. In each graph, the wavelength range for blue (420 nm to 440 nm in this specification), that for green (525 nm to 545 nm in this specification) and that for red (620 nm to 640 nm) are shown hatched.

In any of the seventh, eighth, and ninth examples shown at the top, middle, bottom in FIG. 9, respectively, the reflectance vibrates in relation to the wavelength and the amplitude of vibration takes the minimum value in the wavelength range for green. The reflectance in the seventh to ninth examples are equal to or less than 0.5% in the wavelength range for blue, about 0% in the wavelength range for green, and equal to or less than 0.5% in the wavelength range for red, and take a small value over the entire visible light region.

As illustrated in FIG. 9, according to the organic EL panel 10 according to this embodiment, as the correlation n5>n4>n3 and n5>n6>n7 is held, a small reflectance is achieved over the entire visible light region even when the film thickness d5 of the second inorganic insulating film 40b should vary by about ±10%. This enables reduction of reflectance in the visible light region independently of the accuracy in a film forming process, and thus can improve the light extraction efficiency.

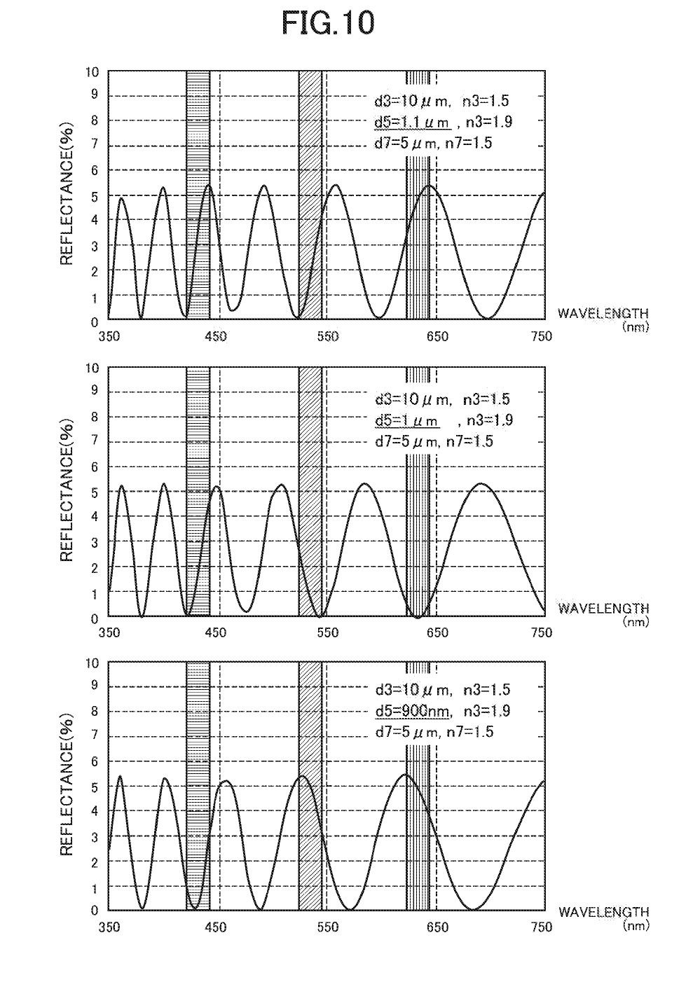

FIG. 10 illustrates a correlation between the reflectance and the light wavelength in second to fourth comparative examples. Each of the second to fourth comparative examples is related to a structure resulting from removing the second intermediate film 41b and the third intermediate film 41c from the sealing film 33 of the organic EL panel 10 according to this embodiment so that the second inorganic insulating film 40b with the film thickness d5 and the refractive index n5 is formed on the first organic insulating film 42a and the second organic insulating film 42b with the film thickness d7 and the refractive index n7 is formed on the second inorganic insulating film 40b. Specifically, the film thickness d3 of the first organic insulating film 42a is 10 μm, or d3=10 μm, and the refractive index n3 of the same is 1.5, or n3=1.5; the film thickness d5 of the second inorganic insulating film 40b is 1 μm, or d5=1 μm, and the refractive index n1 of the same is 1.9, or n1=1.9; the film thickness d7 of the second organic insulating film 42b is 5 μm, or d7=5 μm, and the refractive index n7 of the same is 1.5, or n7=1.5. In the second to fourth comparative examples, the film thickness d5 of the second inorganic insulating film 40b is varied. Specifically, the film thickness d5 of the second inorganic insulating film 40b in the second comparative example, shown at the top in FIG. 10, is 1100 nm, or d5=1100 nm; that in the third comparative example, shown at the middle in FIG. 10, is 1 μm, or d5=1 μm; that in the fourth comparative example, shown at the bottom in FIG. 10, is 900 nm, or d5=900 nm.

In the second to fourth comparative examples, the reflectance in the visible light region vibrates in the range between 0% and 5.5%. The amplitude of vibration is large as compared with that of the organic EL panel 10 according to this embodiment. Additionally, the amplitude of vibration of the reflectance in relation to change in wavelength does not take the minimum value in the visible light region. Thus, deviation of the film thickness and refractive index of the second inorganic insulating film 40b from the respective design values by a few percentages results in unintended increase of the reflectance, which possibly deteriorate the light extraction efficiency. With the reflectance in the wavelength range for red focused, the reflectance is 0 to 0.5% in the third comparative example, shown at the middle in FIG. 10, whereas the reflectance is 3 to 5.5% in the second comparative example, shown at the top in FIG. 10, and 3.5 to 5.5% in the fourth comparative example, shown at the bottom in FIG. 10. As described above, in the comparative examples, variation in the film thickness d5 of the second inorganic insulating film 40b by ±10% results in variation in reflectance by about 3 to 5%. On the contrary, the organic EL panel 10 according to this embodiment can reduce the reflectance in the visible light region to 2% or below, with little possibility that the reflectance unintendedly becomes large even when the film thickness d5 of the second inorganic insulating film 40b should vary by ±10%. This can stably increase the light extraction efficiency.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device, comprising:
a pixel electrode on an insulating surface;
an organic layer on the pixel electrode, the organic layer including a light emitting layer;
an opposed electrode on the organic layer;
a first inorganic insulating film on the opposed electrode;
a first intermediate film on the first inorganic insulating film; and
a first organic insulating film on the first intermediate film,
wherein
a refractive index of the first intermediate film is less than a refractive index of the first inorganic insulating film and greater than a refractive index of the first organic insulating film.

2. The display device according to claim 1, wherein a reflectance of a visible light emitted from the organic layer toward a display surface side and reflected by the first inorganic insulating film, the first intermediate film, and the first organic insulating film changes in relation to a wavelength, and takes a minimum value in a visible light wavelength range.

3. The display device according to claim 1, further comprising:
a second intermediate film on the first organic insulating film;
a second inorganic insulating film on the second intermediate film;
a third intermediate film on the second inorganic insulating film; and
a second organic insulating film on the third intermediate film,
wherein
a refractive index of the second intermediate film is less than a refractive index of the second inorganic insulating film and greater than the refractive index of the first organic insulating film, and
a refractive index of the third intermediate film is less than the refractive index of the second inorganic insulating film and greater than a refractive index of the second organic insulating film.

4. The display device according to claim 3, wherein a reflectance of a visible light emitted from the organic layer toward a display surface side and reflected by the first organic insulating film, the second intermediate film, the second inorganic insulating film, the third intermediate film, and the second organic insulating film oscillates in relation to a wavelength, and an amplitude of oscillation takes a minimum value in the visible light wavelength range.

5. The display device according to claim 1, wherein
the first inorganic insulating film is made using a silicon nitride film,
the first organic insulating film is made of resin containing either acrylic or epoxy, and
the first intermediate film is made using a silicon oxinitride film.

6. The display device according to claim 3, wherein
the first inorganic insulating film and the second inorganic insulating film are each made using a silicon nitride film,
the first organic insulating film is made of resin containing either acrylic or epoxy,
the second organic insulating film is made of one kind of resin selected from a group consisting of resin containing acrylic or epoxy, polyimide, polyethylene naphthalate, and polyethylene terephthalate, and
each of the first intermediate film, the second intermediate film, and the third intermediate film is made using a silicon oxinitride film.
